(19) United States
(12) Patent Application Publication
(10) Pub. No.: US 2026/0052722 A1
(43) Pub. Date: Feb. 19, 2026

(54) JFET WITH ASYMMETRIC GATES

(71) Applicant: Microchip Technology Incorporated, Chandler, AZ (US)

(72) Inventor: Shesh Mani Pandey, Gilbert, AZ (US)

(73) Assignee: Microchip Technology Incorporated, Chandler, AZ (US)

(21) Appl. No.: 18/932,341

(22) Filed: Oct. 30, 2024

Related U.S. Application Data
(60) Provisional application No. 63/684,795, filed on Aug. 19, 2024.

(51) Int. Cl. H01L 29/78; H01L 29/08; H01L 29/10; H01L 29/423; H01L 29/66

(52) U.S. Cl. CPC H10D 30/615; H10D 30/0515; H10D 62/149; H10D 62/328; H10D 62/343; H10D 64/411

(57) ABSTRACT

A junction field-effect transistor with asymmetric gates, and a method of making the same. A channel is constructed of semiconductor material, a source is located at a first end of the channel, and a drain is located at a second end. A first gate is located at and extends along a first side of the channel and creates a first depletion region, and a second gate is located at and extends along a second side of the channel and creates a second depletion region. The gates are physically asymmetric with regard to at least one of their relative position along the channel, their relative size, or their relative shape (e.g., one gate may project into the channel toward the other gate). The physical asymmetry of the first and second gates results in their respective depletion regions being asymmetric, which affects the ability to control electrical current flowing through the channel.

### RELATED APPLICATION

The present U.S. non-provisional patent application is related to and claims priority benefit of an earlier-filed U.S. provisional patent application titled “JFET with Asymmetric Gate,” Ser. No. 63/684,795, filed Aug. 19, 2024. The entire content of the identified earlier-filed application is incorporated by reference as if fully set forth herein.

### FIELD

The present disclosure relates to junction field effect transistors and methods of making them, and more particularly, the various examples described herein concern a junction field-effect transistor with asymmetric gates, and a method of making a junction field-effect transistor with asymmetric gates.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a JFET with asymmetric gates, and a method of making a JFET with asymmetric gates. Broadly, the gates may be physically asymmetric with regard to their relative position along a channel, their relative size, or their relative shape (e.g., one gate may project into the channel toward the other gate). The physical asymmetry of the gates results in their respective depletion regions being asymmetric, which affects the ability to control electrical current flowing through the channel. Examples advantageously provide improved performance, including improved current control, and reduced cost.

An example of a JFET with asymmetric gates may include a channel, a source, a drain, and first and second gates. The channel may be constructed from a semiconductor material, and may include a first end, a second end, a first side, and a second side. The source may be located at the first end of the channel, and the drain may be located at the second end of the channel. The first gate may be located at the first side of the channel and may have a first set of physical characteristics, and the first gate may create a first depletion region. The second gate may be located at the second side of the channel and may have a second set of physical characteristics, and the second gate may create a second depletion region. The first set of physical characteristics may differ from the second set of physical characteristics, resulting in the first and second gates being physically asymmetric and the first and second depletion regions being asymmetric.

The preceding example may further include any one or more of the following features. The first and second sets of physical characteristics may differ with regard to at least one of a relative position of the gates, a relative size of the gates, or a relative shape of the gates. The relative position of the first and second gates may differ in that a first gate upper portion may be positioned at the first side of the channel relatively closer to the source, and a second gate upper portion may be positioned at the second side of the channel relatively further from the source, such that the first and second depletion regions are asymmetric. The first gate may include a first gate lower surface, and the second gate may include a second gate lower surface that is coplanar or otherwise parallel with the first gate lower surface. The relative position of the first and second gates may differ in that a first gate lower portion may be positioned at the first side of the channel relatively closer to the drain, and a second gate lower portion may be positioned at the second side of the channel relatively further from the drain, such that the first and second depletion regions are asymmetric. The first gate may include a first gate upper surface, and the second gate may include a second gate upper surface that is coplanar or otherwise parallel with the first gate upper surface. The relative size of the first and second gates may differ in that a first gate length along the first side of the channel between a first gate upper portion and a first gate lower portion may be larger or smaller than a second gate length along the second side of the channel between a second gate upper portion and a second gate lower portion, such that the first and second depletion regions are asymmetric. The relative shape of the first and second gates may differ in that one of the first and second gates may include a projecting portion that projects into the channel toward an opposite side of the channel, such that the first and second depletion regions are asymmetric.

An example of a method of making a JFET with asymmetric gates may include the following operations. A channel may be constructed from a semiconductor material, the channel including a first end, a second end, a first side, and a second side. A source may be constructed at the first end of the channel, and a drain may be constructed at the second end of the channel. A first gate may be constructed, including implanting a first gate material at the first side of the channel, the first gate having a first set of physical characteristics, and the first gate creating a first depletion region. A second gate may be constructed, including implanting a second gate material at the second side of the channel, the second gate having a second set of physical characteristics, and the second gate creating a second depletion region. The first set of physical characteristics may differ from the second set of physical characteristics with regard to at least one of a relative position of the first and second gates, a relative size of the first and second gates, and a relative shape of the first and second gates, resulting in the first and second gates being physically asymmetric and the first and second depletion regions being asymmetric.

The preceding example may further include any one or more of the following features. The relative position of the first and second gates may differ in that a first gate upper portion may be positioned at the first side of the channel relatively closer to the source, and a second gate upper portion may be positioned at the second side of the channel relatively further from the source, such that the first and second depletion regions are asymmetric. The first gate may include a first gate lower surface, and the second gate may include a second gate lower surface that is coplanar with the first gate lower surface. The relative position of the first and second gates may differ in that a first gate lower portion may be positioned at the first side of the channel relatively closer to the drain, and a second gate lower portion may be positioned at the second side of the channel relatively further from the drain, such that the first and second depletion regions are asymmetric. The first gate may include a first gate upper surface, and the second gate may include a second gate upper surface that is coplanar with the first gate upper surface. The relative size of the first and second gates may differ in that a first gate length along the first side of the channel between a first gate upper portion and a first gate lower portion may be larger or smaller than a second gate length along the second side of the channel between a second gate upper portion and a second gate lower portion, such that the first and second depletion regions are asymmetric. The relative shape of the first and second gates may differ in that one of the first and second gates may include a projecting portion that projects into the channel toward an opposite side of the channel, such that the first and second depletion regions are asymmetric.

This summary is not intended to identify essential features of the examples, and is not intended to be used to limit the scope of the claims. These and other aspects of the present examples are described below in greater detail.

### DESCRIPTION OF DRAWINGS

Examples are described in detail below with reference to the attached drawing figures, wherein:

FIG. 1 is a cross-sectional elevation view of an example of a JFET with asymmetric gates, wherein the gates are asymmetric at least with regard to their relative positions;

FIG. 2 is a cross-sectional elevation view of another example of a JFET with asymmetric gates, wherein the gates are asymmetric at least with regard to their relative sizes;

FIG. 3 is a cross-sectional elevation view of another example of a JFET with asymmetric gates, wherein the gates are asymmetric at least with regard to their relative shapes;

FIG. 4 is a cross-sectional elevation view of another example of a JFET with asymmetric gates, wherein the gates are asymmetric at least with regard to both their relative positions and their relative shapes;

FIG. 5 is a cross-sectional elevation view of another example of a JFET with asymmetric gates, wherein the gates are asymmetric at least with regard to both their relative positions and their relative sizes;

FIG. 6 is a flowchart of operations in a first example of a method of manufacturing a JFET with asymmetric gates;

FIG. 7 is a flowchart of operations in a second example of a method of manufacturing a JFET with asymmetric gates;

FIG. 8A is a cross-sectional elevation view of the result of an operation in the method of FIG. 7, wherein an implantation of a source and a gate are shown;

FIG. 8B is a cross-sectional elevation view of the result of an operation in the method of FIG. 7, wherein an etching of trenches is shown;

FIG. 8C is a cross-sectional elevation view of the result of an operation in the method of FIG. 7, wherein an etching of a second trench and an implantation of a second gate is shown in manufacturing the JFET of FIG. 1;

FIG. 8D is a cross-sectional elevation view of the result of an operation in the method of FIG. 7, wherein an etching of a second trench and an implantation of a second gate is shown in manufacturing the JFET of FIG. 4;

FIG. 8E is a cross-sectional elevation view of the result of an operation in the method of FIG. 7, wherein electrical terminals are added to the structure of FIG. 8C;

FIG. 8F is a cross-sectional elevation view of the result of an operation in the method of FIG. 7, wherein electrical terminals are added to the structure of FIG. 8D;

FIG. 9 is a flowchart of operations in a third example of a method of manufacturing a JFET with asymmetric gates;

FIG. 10A is a cross-sectional elevation view of the result of an operation in the method of FIG. 9, wherein an implantation of a source and a first gate are shown;

FIG. 10B is a cross-sectional elevation view of the result of an operation in the method of FIG. 9, wherein an etching of trenches is shown;

FIG. 10C is a cross-sectional elevation view of the result of an operation in the method of FIG. 9, wherein an implantation of a second gate is shown; and

FIG. 10D is a cross-sectional elevation view of the result of an operation in the method of FIG. 9, wherein an addition of electrical contacts is shown in manufacturing the JFET of FIG. 5.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples provide a JFET with asymmetric gates, and a method of making a JFET with asymmetric gates. The gates may be physically asymmetric with regard to their relative position along the channel, their relative size, or their relative shape (e.g., one gate may project into the channel toward the other gate). The physical asymmetry of the gates results in their respective depletion regions being asymmetric, which affects the ability to control electrical current flowing through the channel. Examples advantageously provide improved performance, including improved current control, and reduced cost.

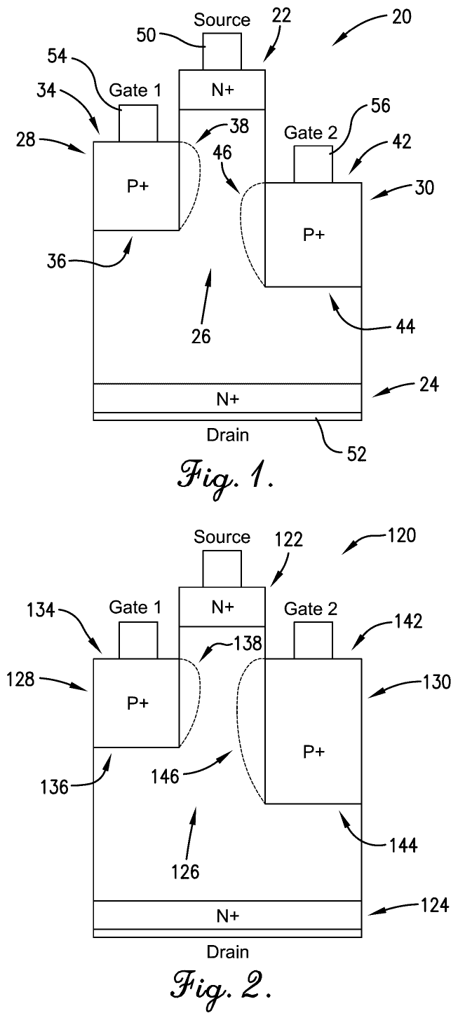

Referring to FIGS. 1-5, various examples of JFETs 20, 120, 220, 320, 420 with asymmetric gates are shown. Each of these JFETs may include a source 22, a drain 24, a channel 26, a first gate 28, and a second gate 30 (in FIGS. 2-5, the reference numbers for these same structures are incremented by an additional 100 for each subsequent figure). The source 22 may be located at a first end of the channel 26 and may provide an entrance for the majority charge carriers (e.g., electrons for N-channel) into the channel 26. The source 22 may be constructed from or include N+ material. The drain 24 may be located at a second end of the channel 26, spaced apart from the source 22, and may provide an exit for the majority charge carriers from the channel 26. The drain 24 may be constructed from or include N+ material. The channel 26 may be a region between the source 22 and the drain 24 through which the majority charge carriers move, i.e., through which electrical current flows. The channel 26 may be constructed from or include N-type semiconductor material. The first gate 28 may be located at a first side of the channel 26, may include a top surface 34 and a bottom surface 36, and, in operation, may create a first depletion region 38 (i.e., a region in which the majority charge carriers have been depleted). The first gate 28 may be constructed from or include P+ material. The second gate 30 may be located at a second side of the channel 26, spaced apart across the channel 26 from the first gate 28, may include a top surface 42 and a bottom surface 44, and, in operation, may create a second depletion region 46. The second gate 30 may be constructed from or include P+ material. The source 22 may include a source electrical terminal 50, the drain may include a drain electrical terminal 52, the first gate 28 may include a first gate electrical terminal 54, and the second gate 30 may include a second gate electrical terminal 56.

The first and second gates 28, 30 may be physically asymmetric with regard to at least one of their relative position along the channel 26, their relative size, and their relative shapes. This physical asymmetry results in the depletion regions 38, 46 being asymmetric. The specific relative position, size, or shape of the gates for any particular application may depend on the desired control of the electrical current through the channel 26.

In the example of JFET 20 of FIG. 1, the first and second gates 28, 30 are asymmetric at least with regard to their relative position. More specifically, the second gate 30 is shown positioned farther from the source 22 and closer to the drain 24 than the first gate 28. Further, the top surface 34 of the first gate 28 is shown higher, or closer to the source 22, than the top surface 42 of the second gate 30, and the bottom surface 44 of the second gate 30 is shown lower, or closer to the drain 24, than the bottom surface 36 of the first gate 28. Thus, in this example, the physical asymmetry involves the asymmetric position of the first and second gates 28, 30, which results in asymmetric depletion regions 38, 46.

In the JFET 120 of FIG. 2, the first and second gates 128, 130 are asymmetric at least with regard to their relative size. More specifically, the second gate 130 is shown as being larger, or longer, and extending farther along the side of the channel 126 than does the first gate 128. The top surface 134 of the first gate 128 is shown as being coplanar with the top surface 142 of the second gate 130, and the bottom surface 144 of the second gate 130 is shown lower, or closer to the drain 124, than the bottom surface 136 of the first gate 128. Thus, in this example, the physical asymmetry involves the asymmetric size of the first and second gates 128, 130, which results in asymmetric depletion regions 138, 146.

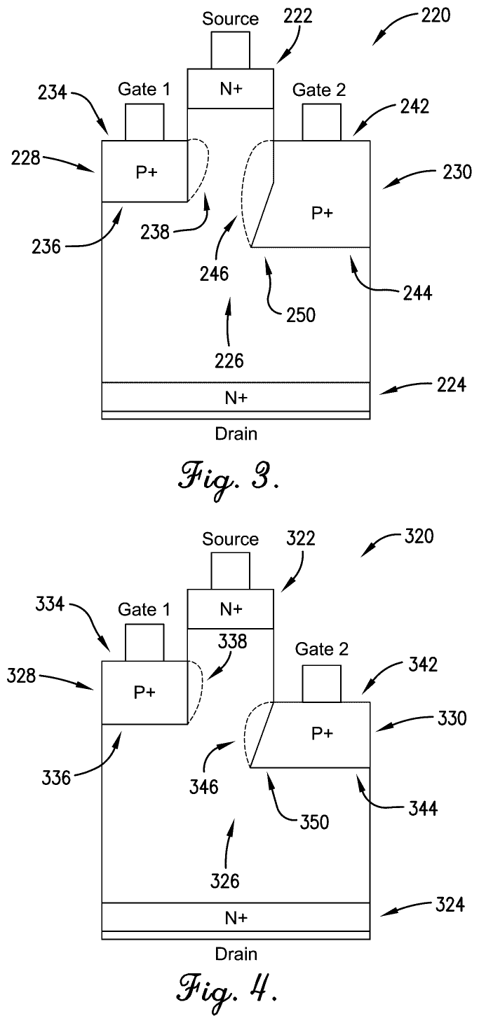

In the JFET 220 of FIG. 3, the first and second gates 228, 230 are asymmetric at least with regard to their relative shape. More specifically, the second gate 230 is shown as including a projection 250 extending into the channel 226 toward the first side of the channel 226, wherein the first gate 228 does not include a projection. Further, the top surface 234 of the first gate 228 is shown as being coplanar with the top surface 242 of the second gate 230, and the bottom surface 244 of the second gate 230 is shown lower, or closer to the drain 224, than the bottom surface 236 of the first gate 228. In this example, the physical asymmetry involves both the asymmetric shape and the asymmetric size of the first and second gates 228, 230, which results in asymmetric depletion regions 238, 246.

In the JFET 320 of FIG. 4, the first and second gates 328, 330 are asymmetric at least with regard to both their relative position and their relative shape. More specifically, the second gate 330 is shown positioned farther from the source 322 and closer to the drain 324 than the first gate 328. The top surface 334 of the first gate 28 is shown higher, or closer to the source 322, than the top surface 342 of the second gate 330, and the bottom surface 344 of the second gate 330 is shown lower, or closer to the drain 324, than the bottom surface 336 of the first gate 328. Further, the second gate 330 is shown as including a projection 350 extending into the channel 326 toward the first side of the channel 326, wherein the first gate 328 does not include a projection. Thus, in this example, the physical asymmetry is in both the asymmetric position and the asymmetric shape of the first and second gates 328, 330, which results in asymmetric depletion regions 338, 346.

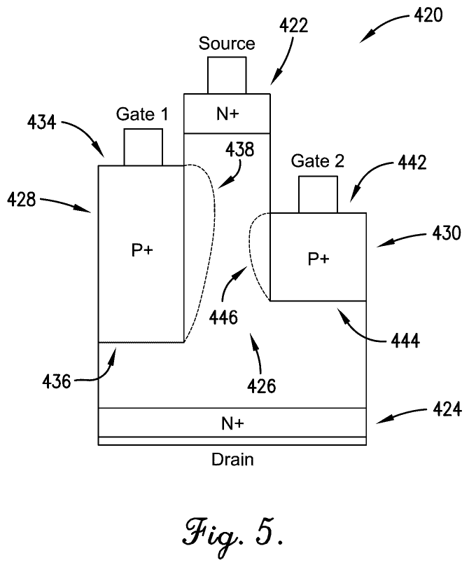

In the JFET 420 of FIG. 5, the first and second gates 428, 430 are asymmetric at least with regard to both their relative position and their relative size. More specifically, the first gate 428 is shown as being larger, or longer, and extending farther along the side of the channel 426 than does the second gate 430. Further, the second gate 430 is shown positioned both farther from the source 422 and further from the drain 424 than the first gate 428. The top surface 434 of the first gate 428 is shown higher, or closer to the source 422, than the top surface 442 of the second gate 430, and the bottom surface 436 of the first gate 428 is shown lower, or closer to the drain 424, than the bottom surface 444 of the second gate 430. Thus, in this example, the physical asymmetry is in both the asymmetric position and the asymmetric size of the first and second gates 428, 430, which results in asymmetric depletion regions 438, 446.

One with ordinary skill will appreciate that each asymmetry in size, shape, or position may be applicable to any gate or combination of gates, and may be combined with any other such asymmetry without departing from the scope of the present disclosure.

In operation, an input voltage, Vds, may be applied across the first and second electrical terminals 50, 52 to cause electron drift/movement from the source 22 to the drain 24, and a control voltage, Vgs, may be applied across the first, third, and fourth electrical terminals 50, 54, 56 to control the width of the depletion regions 38, 46 at the PN junctions where the charge carriers of the P- and N-type materials diffuse into each other, which “depletes” the available concentrations of majority charge carrier in each material, and thereby control the current, Id, from the drain 24 to source 22. Thus, the source 22, the first gate 28, and the second gate 30 may cooperate under Vgs to control the current, Id, through the channel 26. If Vgs=0 V and Vds>0 V, electrons drift, or move, from the source to the drain, resulting in a current, Id, from the drain 24 to the source 22, and increased depletion regions at the PN junctions. If Vds=pinch-off voltage (Vp), then the depletion regions increase in size and grow sufficiently close to each other across the channel 26 that the current, Id, through the channel cannot increase and so is at its maximum, Id=(max drain current (Idss)). In the present examples, the physical asymmetry of the first and second gates 28, 30 results in the asymmetry of the depletion regions 38, 46 which allows for greater flexibility and control over Id.

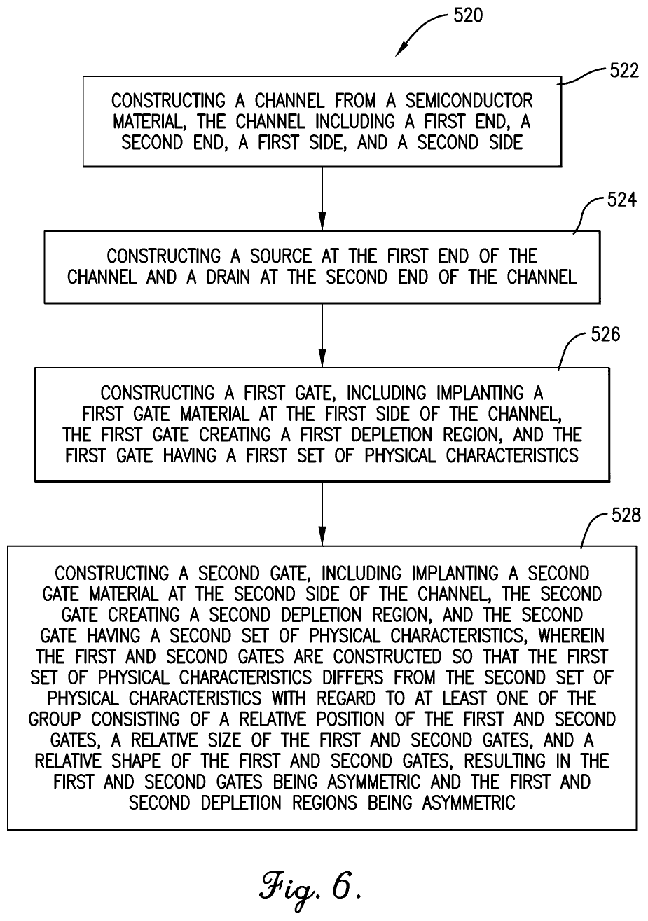

Referring to FIG. 6, an example of a method 520 of manufacturing the JFETs 20, 120, 220, 320, 420 with asymmetric gates of FIGS. 1-5 may include the general operations set forth below. A channel 26 may be constructed from a semiconductor material, and the channel 26 may include a first end, a second end, a first side, and a second side, as shown in 522. A source 22 may be constructed at the first end of the channel 26, and a drain 24 may be constructed at the second end of the channel 26, as shown in 524. A first gate 28 may be constructed, including implanting a first gate material at the first side of the channel 26, the first gate 28 having a first set of physical characteristics, and the first gate 28 creating a first depletion region 38, as shown in 526. A second gate 30 may be constructed, including implanting a second gate material at the second side of the channel 26, the second gate 30 having a second set of physical characteristics, and the second gate creating a second depletion region 46, as shown in 528. The first and second gates 28, 30 may be constructed so that the first set of physical characteristics differs from the second set of physical characteristics with regard to at least one of a relative position of the first and second gates 28, 30, a relative size of the first and second gates 28, 30, and a relative shape of the first and second gates 28, 30, resulting in the first and second gates 28, 30 being physically asymmetric and the first and second depletion regions 38, 46 being asymmetric.

The relative position of the first and second gates may differ in that an upper portion of the first gate may be positioned at the first side of the channel relatively closer to the source, and an upper surface of the second gate may be positioned at the second side of the channel relatively further from the source, such that the first and second depletion regions are asymmetric. Further, the first gate may include a first gate lower surface, and the second gate may include a second gate lower surface that is coplanar with the first gate lower surface. The relative position of the first and second gates may differ in that a lower portion of the first gate is positioned at the first side of the channel relatively closer to the drain and a lower surface of the second gate is positioned at the second side of the channel relatively further from the drain, such that the first and second depletion regions are asymmetric. Further, the first gate may include a first gate upper surface, and the second gate includes a second gate upper surface that is coplanar with the first gate upper surface.

The relative size of the first and second gates may differ in that a first length of the first gate along the first side of the channel between an upper portion of the first gate, and a lower portion of the first gate is greater than a second length of the second gate along the second side of the channel between an upper portion of the second gate and a lower portion of the second gate, such that the first and second depletion regions are asymmetric.

The relative shape of the first and second gates may differ in that the second gate includes a projecting second portion that extends into the channel toward the first side of the channel, such that the first and second depletion regions are asymmetric.

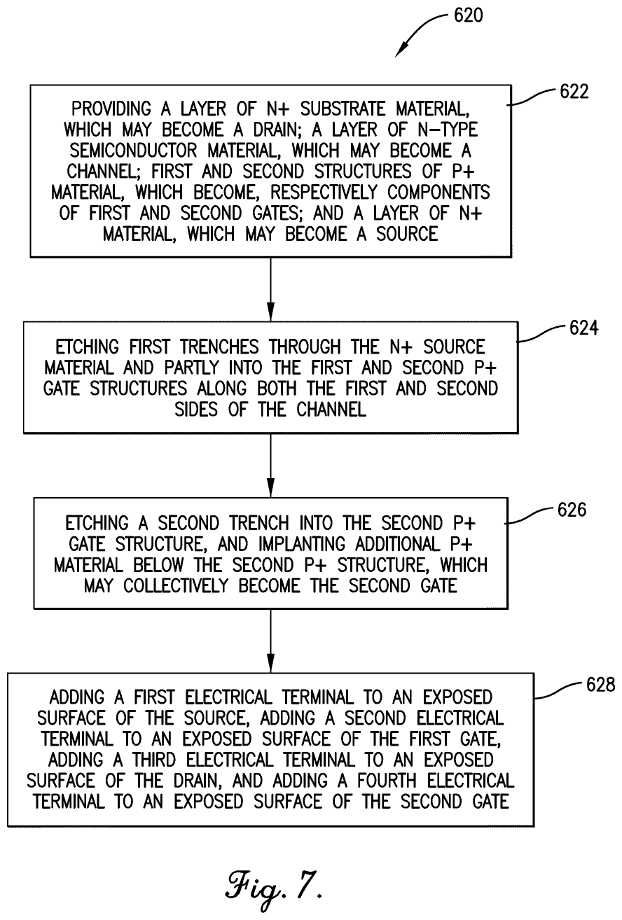

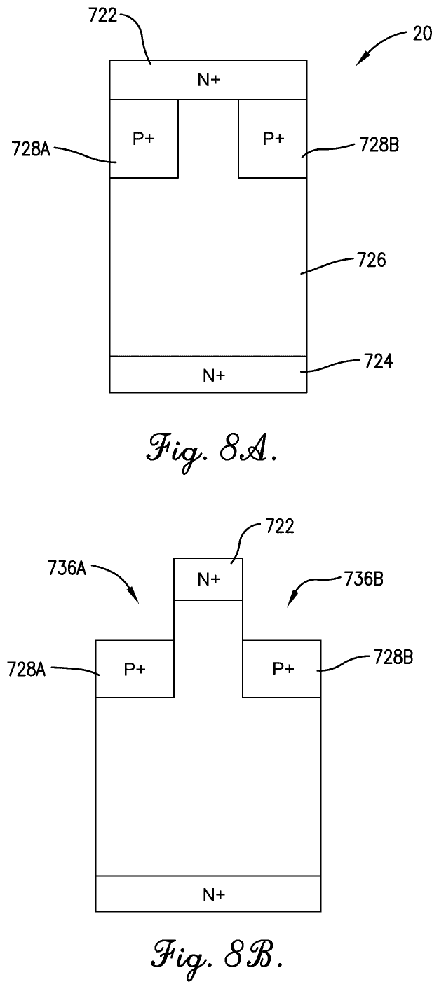

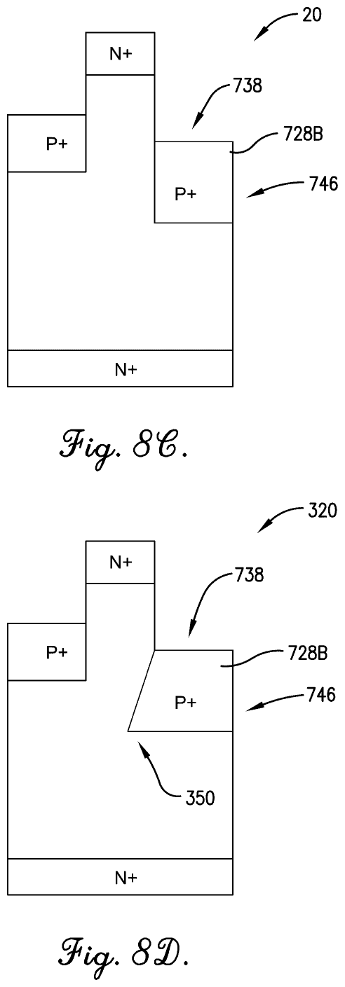

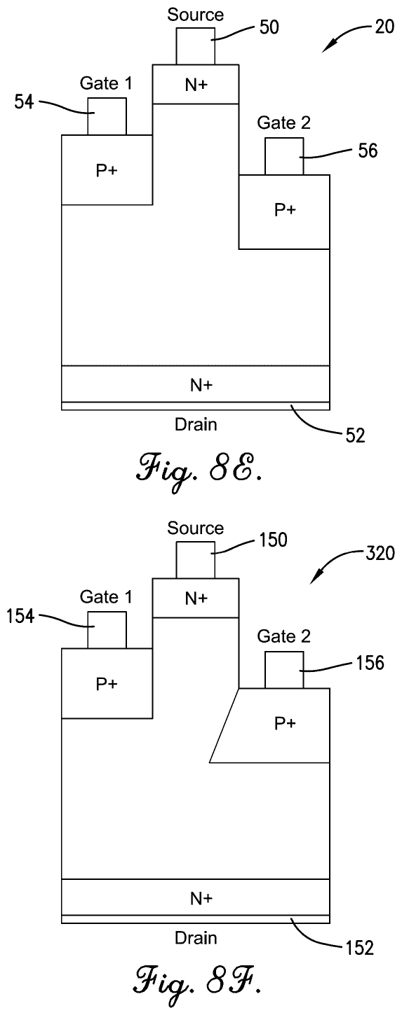

Referring to FIG. 7, an example of a method 620 of manufacturing the JFETs 20, 320 with asymmetric gates of FIGS. 1 and 4 may include the operations set forth below. Referring additionally to FIGS. 8A-8D, example results are shown of the operations of the method 620 and intermediate stages of production of the JFETs 20 and 320. The method 620 may begin with a layer of N+ substrate material 724, which may become the drain 24; a layer of N-type semiconductor material 726 which may become the channel 26; first and second structures of P+ material 728A, 728B, which become, respectively components of the first and second gates 28, 30; and a layer of N+ material 722 which may become the source 22, as shown in 622 and seen in FIG. 8A.

First trenches 736A, 736B may be etched through the N+ source material 722 and partly into the first and second P+ gate structures 728A, 728B along both the first and second sides of the channel 26, as shown in 624 and seen in FIG. 8B. A second trench 738 may be etched into the second P+ gate structure 728B, and, further, additional P+ material 746 may be implanted below the second P+ structure 728B, which may collectively become the second gate 30, as shown in 626 and seen in FIGS. 8C and 8D. FIG. 8C shows the creation of the example of the JFET 20 of FIG. 1, and FIG. 8D shows the creation of the example of the JFET 320 of FIG. 4, wherein the latter includes the projection 350 into the channel 226. It will be appreciated that the method 620 may be modified to manufacture the example JFETs 120, 220 of FIGS. 2 and 3 by eliminating the creation of the second trench 738 so that the upper surfaces of the first and second gates remain coplanar. A source electrical terminal 50, 150 a drain electrical terminal 52, 152 a first gate electrical terminal 54, 154 and a second gate electrical terminal 56, 156 may be added, as shown in 628 and seen in FIGS. 8E and 8F. Additional processing may occur as desired.

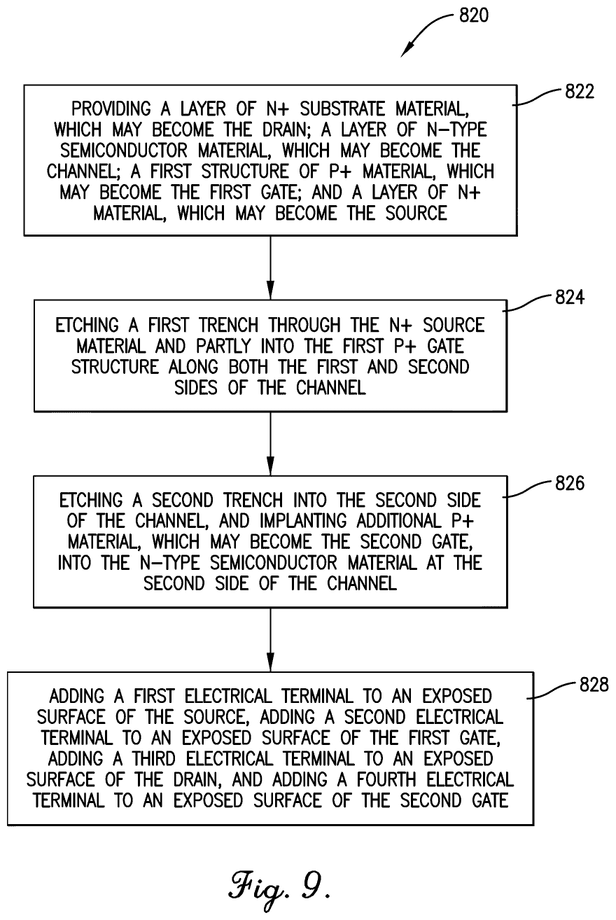

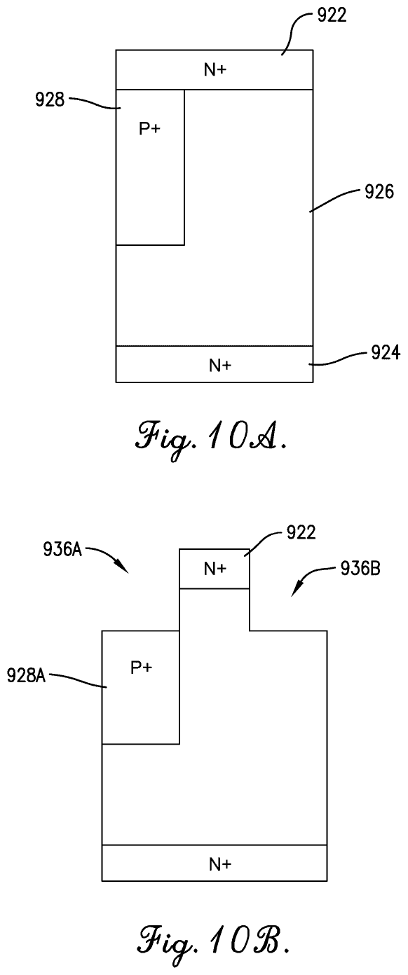

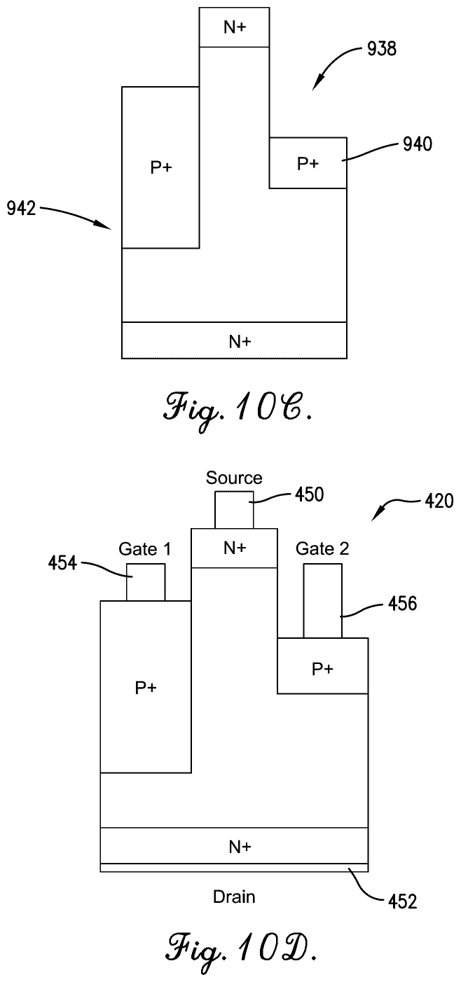

Referring to FIG. 9, an example of a method 820 of manufacturing the JFET 420 with asymmetric gates of FIG. 5 may include the operations set forth below. Referring additionally to FIGS. 10A-10D, example results are shown of the operations of the method 820 and intermediate stages of production of the JFET 420. The method 820 may begin with a layer of N+ substrate material 924, which may become the drain 424; a layer of N-type semiconductor material 926 which may become the channel 426; a first structure of P+ material 928 which may become the first gate 428; and a layer of N+ material 922 which may become the source 422, as shown in 822 and seen in FIG. 10A.

First trenches 936A, 936B may be etched through the N+ source material 922 and partly into the first P+ gate structure 928A along both the first and second sides of the channel 426, as shown in 824 and seen in FIG. 10B. A second trench 938 may be etched into the second side of the channel 426, and additional P+ material 940 which may become the second gate 430 may be implanted into the N-type semiconductor material 926 at the second side of the channel, and, further, additional P+ material 942 may be implanted below the first P+ gate structure 928A, which may collectively become the first gate, as shown in 826 and seen in FIG. 10C. A source electrical terminal 450, a drain electrical terminal 452, a first gate electrical terminal 454, and a second gate electrical terminal 456 may be added, as shown in 828 and seen in FIG. 10D. Additional processing may occur as desired.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A junction field-effect transistor with asymmetric gates, the junction field-effect transistor comprising:
a channel constructed from a semiconductor material, the channel including a first end, a second end, a first side, and a second side;
a source located at the first end of the channel;
a drain located at the second end of the channel;
a first gate located at the first side of the channel, the first gate having a first set of physical characteristics, and the first gate creating a first depletion region; and
a second gate located at the second side of the channel, the second gate having a second set of physical characteristics, and the second gate creating a second depletion region,
wherein the first set of physical characteristics differs from the second set of physical characteristics, resulting in the first and second gates being physically asymmetric and the first and second depletion regions being asymmetric.

2. The junction field-effect transistor of claim 1, wherein the first set of physical characteristics differs from the second set of physical characteristics with regard to at least one of the group consisting of: a relative position of the first and second gates, a relative size of the first and second gates, and a relative shape of the first and second gates.

3. The junction field-effect transistor of claim 2, wherein the relative position of the first and second gates differs in that a first gate upper portion is positioned at the first side of the channel relatively closer to the source, and a second gate upper portion is positioned at the second side of the channel relatively further from the source, such that the first and second depletion regions are asymmetric.

4. The junction field-effect transistor of claim 2, wherein the relative position of the first and second gates differs in that a first gate lower portion is positioned at the first side of the channel relatively closer to the drain and a second gate lower portion is positioned at the second side of the channel relatively further from the drain, such that the first and second depletion regions are asymmetric.

5. The junction field-effect transistor of claim 4, wherein the first gate includes a first gate upper surface, and the second gate includes a second gate upper surface that is coplanar with the first gate upper surface.

6. The junction field-effect transistor of claim 2, wherein the relative size of the first and second gates differs in that a first gate length along the first side of the channel between a first gate upper portion and a first gate lower portion is greater than a second gate length along the second side of the channel between a second gate upper portion and a second gate lower portion, such that the first and second depletion regions are asymmetric.

7. The junction field-effect transistor of claim 2, wherein the relative shape of the first and second gates differs in that one of the first and second gates includes a projecting portion that projects into the channel toward an opposite side of the channel, such that the first and second depletion regions are asymmetric.

8. A junction field-effect transistor with asymmetric gates, the junction field-effect transistor comprising:
a channel constructed from an epitaxial N-type semiconductor material, the channel including a first end, a second end, a first side, and a second side;
a source constructed from an implanted N+ material and located at the first end of the channel;
a drain constructed from the implanted N+ material and located at the second end of the channel;
a first gate constructed from an implanted first P+ material located at the first side of the channel, the first gate having a first set of physical characteristics, and the first gate creating a first depletion region; and
a second gate constructed from an implanted second P+ material located at the second side of the channel, the second gate having a second set of physical characteristics, and the second gate creating a second depletion region,
wherein the first set of physical characteristics differs from the second set of physical characteristics with regard to at least one of the group consisting of: a relative position of the first and second gates, a relative size of the first and second gates, and a relative shape of the first and second gates, resulting in the first and second gates being physically asymmetric and the first and second depletion regions being asymmetric.

9. The junction field-effect transistor of claim 8, wherein the relative position of the first and second gates differs in that a first gate upper portion is positioned at the first side of the channel relatively closer to the source, and a second gate upper portion is positioned at the second side of the channel relatively further from the source, such that the first and second depletion regions are asymmetric.

10. The junction field-effect transistor of claim 8, wherein the relative position of the first and second gates differs in that a first gate lower portion is positioned at the first side of the channel relatively closer to the drain and a second gate lower portion is positioned at the second side of the channel relatively further from the drain, such that the first and second depletion regions are asymmetric.

11. The junction field-effect transistor of claim 8, wherein the relative size of the first and second gates differs in that a first gate length along the first side of the channel between a first gate upper portion and a first gate lower portion is greater than a second gate length along the second side of the channel between a second gate upper portion and a second gate lower portion, such that the first and second depletion regions are asymmetric.

12. The junction field-effect transistor of claim 8, wherein the relative shape of the first and second gates differs in that one of the first and second gates includes a projecting portion that projects into the channel toward an opposite side of the channel, such that the first and second depletion regions are asymmetric.

13. A method of making a junction field-effect transistor with asymmetric gates, the method comprising:
constructing a channel from a semiconductor material, the channel including a first end, a second end, a first side, and a second side;
constructing a source at the first end of the channel and a drain at the second end of the channel;
constructing a first gate, including implanting a first gate material at the first side of the channel, the first gate having a first set of physical characteristics, and the first gate creating a first depletion region; and
constructing a second gate, including implanting a second gate material at the second side of the channel, the second gate having a second set of physical characteristics, and the first gate creating a second depletion region,
wherein the first set of physical characteristics differs from the second set of physical characteristics with regard to at least one of the group consisting of: a relative position of the first and second gates, a relative size of the first and second gates, and a relative shape of the first and second gates, resulting in the first and second gates being physically asymmetric and the first and second depletion regions being asymmetric.

14. The method of claim 13, wherein the relative position of the first and second gates differs in that a first gate upper portion is positioned at the first side of the channel relatively closer to the source, and a second gate upper portion is positioned at the second side of the channel relatively further from the source, such that the first and second depletion regions are asymmetric.

15. The method of claim 13, wherein the relative position of the first and second gates differs in that a first gate lower portion is positioned at the first side of the channel relatively closer to the drain and a second gate lower portion is positioned at the second side of the channel relatively further from the drain, such that the first and second depletion regions are asymmetric.

16. The method of claim 15, wherein the first gate includes a first gate upper surface, and the second gate includes a second gate upper surface that is coplanar with the first gate upper surface.

17. The method of claim 13, wherein the relative size of the first and second gates differs in that a first gate length along the first side of the channel between a first gate upper portion and a first gate lower portion is greater than a second gate length along the second side of the channel between a second gate upper portion and a second gate lower portion, such that the first and second depletion regions are asymmetric.

18. The method of claim 13, wherein the relative shape of the first and second gates differs in that the one of the first and second gates includes a projecting portion that projects into the channel toward an opposite side of the channel, such that the first and second depletion regions are asymmetric.
